(19) United States
(12) Patent Application Publication
(10) Pub. No.: US 2009/0109609 A1
(43) Pub. Date: Apr. 30, 2009

(54) STORAGE SERVER

(75) Inventors: HSIU-CHANG LAI, Tu-Cheng (TW); KE SUN, Shenzhen (CN); ZHEN-XING YE, Shenzhen (CN); MING-KE CHEN, Shenzhen (CN); XIAO-ZHU CHEN, Shenzhen (CN)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD ., Shenzhen City (CN); HON HAI PRECISION INDUSTRY CO., LTD., Tu-Cheng (TW)

(21) Appl. No.: 11/957,417

(22) Filed: Dec. 15, 2007

(30) Foreign Application Priority Data
Oct. 24, 2007 (CN) 200710202239.7

(51) Int. Cl. H05K 5/02

(52) U.S. Cl. 361/679.39

(57) ABSTRACT

A storage server includes a base, a storage module, and a controller module. The storage module is removably received in the base at a side thereof. The storage module includes a bracket, at least one hard disk, and a backplane. The bracket defines at least one receiving space therein. The at least one hard disk is received in the receiving space. The backplane is fixed to the bracket facing the hard disk, for being electrically connected to the hard disk. At least one first connector is fixed to the backplane. The controller module is received at an opposite side of the base and capable of receiving a plurality of auxiliary components to serve the at least one hard disk via the backplane of the bracket. The controller module has at least one second connector for electrically connecting to the first connector of the backplane.

### BACKGROUND

1. Field of the Invention

The present invention generally relates to a storage server.

2. Description of Related Art

A storage server usually includes a chassis for fixing hard disks and auxiliary components such as power supplies, controllers to serve the hard disks. A bracket is installed at a front end of the chassis for receiving the hard disks therein, and the auxiliary components are installed at a rear end of the chassis. Commonly, a backplane is installed to the chassis and between the bracket and the auxiliary components, connectors for connecting to the hard disks and the auxiliary components are respectively fixed to opposite sides of the backplane.

There are two types of hard disks that are commonly used, the 3.5 inch hard disks and the 2.5 inch hard disks. The two types of hard disks have different sizes, and arrangements of connectors of them are distinct. Brackets for receiving the two types of hard disks have different sizes accordingly. Therefore, the auxiliary components, the chassis, and the backplanes should be particularly designed for the two types of hard disks. Therefore, when one type of hard disk should be replaced by the other type of hard disk, the corresponding auxiliary components, chassis, and bracket should also be replaced, which is costly. Therefore, a need exists in the industry to provide a storage server compatible with the two types of hard disks.

### SUMMARY

In one embodiment, a storage server includes a base, a storage module, and a controller module. The storage module is removably received in the base at a side thereof. The storage module includes a bracket, at least one hard disk, and a backplane. The bracket defines at least one receiving space therein. The at least one hard disk is received in the receiving space. The backplane is fixed to the bracket facing the hard disk, for being electrically connected to the hard disk. At least one first connector is fixed to the backplane. The controller module is received at an opposite side of the base and capable of receiving a plurality of auxiliary components to serve the hard disks via the backplane of the bracket. The controller module has at least one second connector for electrically connecting to the first connector of the backplane.

Other advantages and novel features of the storage server will become more apparent from the following detailed description of preferred embodiments when taken in conjunction with the accompanying drawings, in which:

### BRIEF DESCRIPTION OF THE DRAWINGS

FIG. 1 is an exploded, isometric view of a storage server in accordance with an exemplary embodiment of the present invention incorporating with a first storage module that has a first type of hard disks, the storage server includes a base and a controller module;

FIG. 2 is an exploded, isometric view of the first storage module of FIG. 1;

FIG. 3 is an assembled view of FIG. 1;

FIG. 4 is an exploded, isometric view of the base and the controller module of FIG. 1, together with a second storage module that has a second type of hard disks; and

FIG. 5 is an exploded, isometric view of the second storage module of FIG. 4.

### DETAILED DESCRIPTION

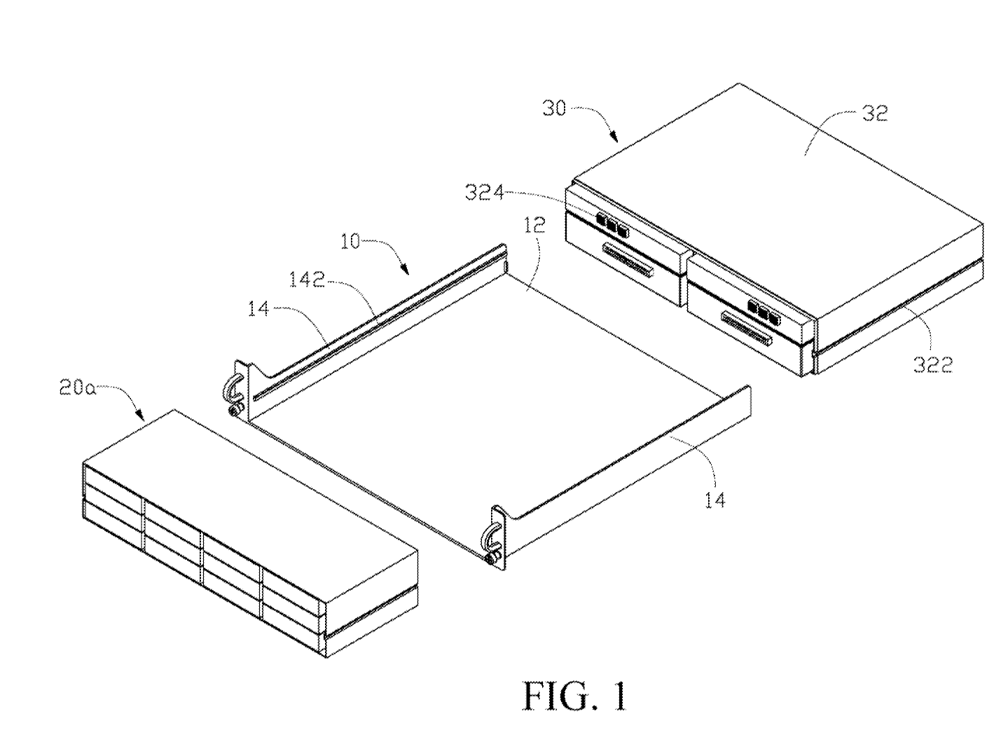

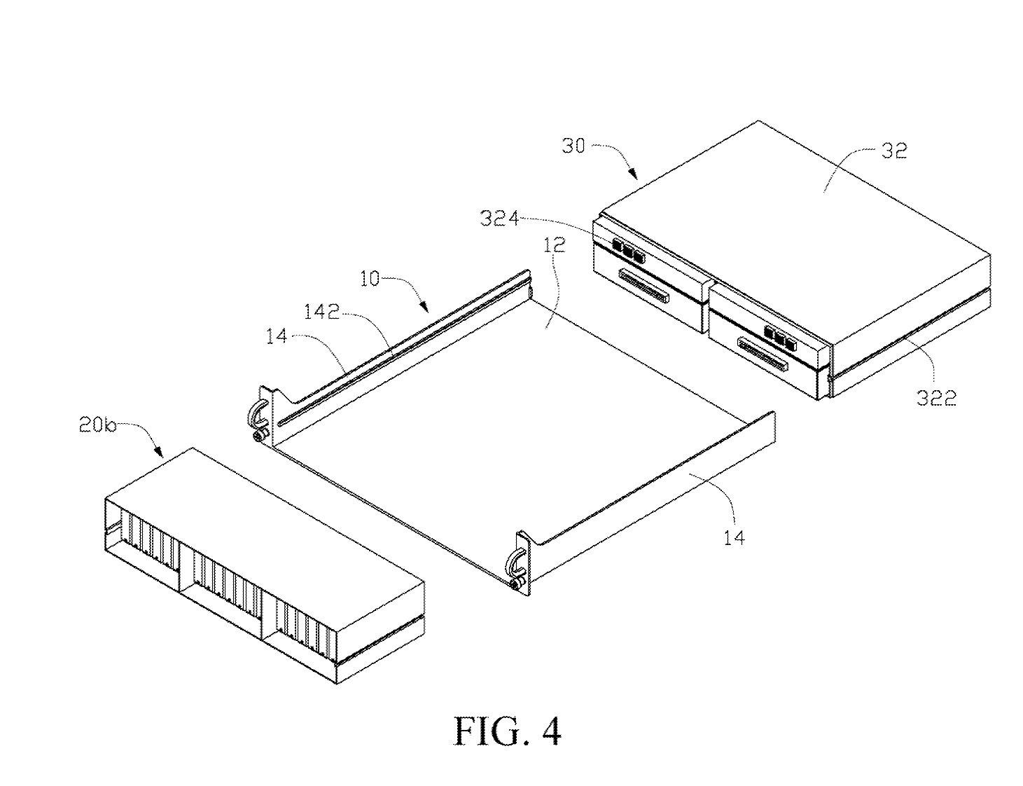

Referring to FIGS. 1 and 4, a storage server in accordance with an exemplary embodiment selectively incorporates a first storage module 20a and a second storage module 20b. The storage server includes a base 10 and a controller module 30.

The base 10 that is generally U-shaped includes a bottom wall 12 and two sidewalls 14 perpendicularly extending from two opposite sides of the bottom wall 12. On an inner surface of each sidewall 14, a guiding portion 142 is formed. The guiding portion 142 can be a protrusion protruding from a corresponding sidewall 14, and is generally parallel to the bottom wall 12.

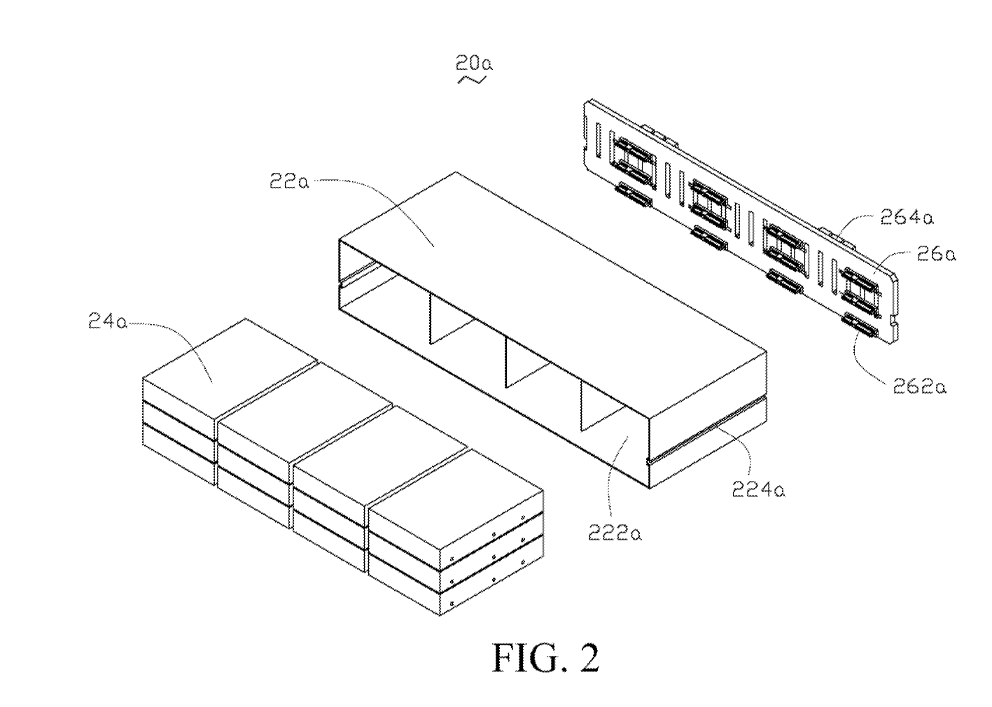

Referring also to FIG. 2, the first storage module 20a includes a bracket 22a, a plurality of first type of hard disks 24a, and a backplane 26a. The bracket 22a is generally box-shaped with two openings defined at opposite sides thereof respectively. The bracket 22a is segmented by a plurality of baffles (not labeled) into a plurality of receiving spaces 222a, each receiving space 222a receiving predetermined amount of the first type of hard disks 24a. A slot 224a is defined in an outer surface of each side of the bracket 22a, for engaging the corresponding guiding portion 142 of the base 10. In the embodiment, the hard disks 24a are 3.5 inch hard disks.

The backplane 26a is fixed to the bracket 22a at one of the openings. The backplane 26a has a plurality of first connectors 262a fixed to a side thereof, facing an inner space of the bracket 22a, corresponding to the first type of hard disks 24a. The first connectors 262a are used for being connected to the connectors (not shown) provided on the first type of hard disks 24a. Further, at least a second connector 264a is fixed to an opposite side of the backplane 26a.

The controller module 30 includes a frame 32, and a plurality of auxiliary components such as power supplies, controllers, and other components received in the frame 32a to serve the first type of hard disks 24a. A slot 322 is defined in an outer surface of each side of the frame 32. The slot 322 is used for engaging with a corresponding guiding portion 142 of the base 10. The controller module 30 further includes at least one third connector 324, for being connected to the second connector 264a on the backplane 26a of the first storage module 20a.

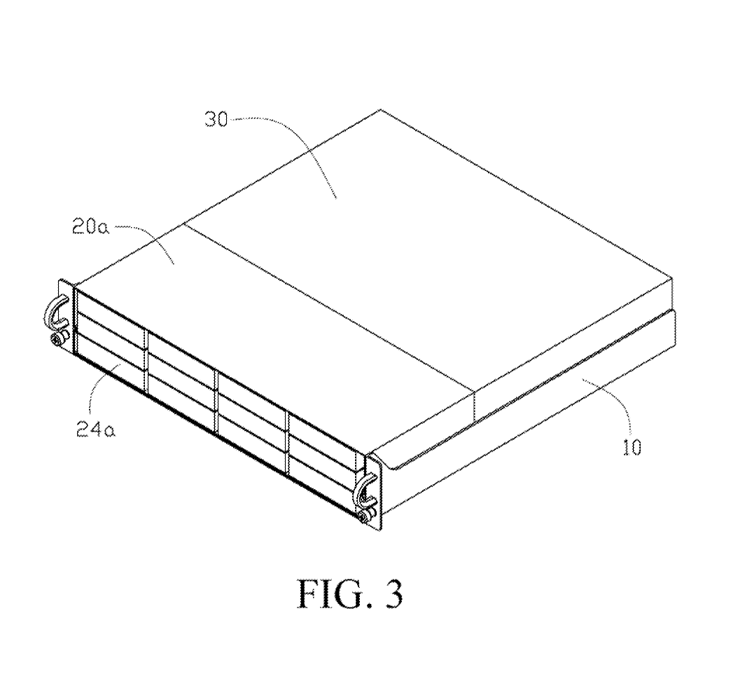

Referring also to FIG. 3, in assembly, the first type of hard disks 24a are stacked to be received in the receiving spaces 222a of the bracket 22a. The connectors of the first hard disks 24a are electrically coupled to the first connectors 262a on the backplane 26a of the first storage module 20a. The bracket 22a, together with the first type of hard disks 24a, slide along the guiding portion 142 into the base 10 from a side, with each slot 224a engaging with a corresponding guiding portion 142. The controller module 30 slides along the guiding portion 142 to be received in the base 10 from the opposite side, with each slot 322 engaging with a corresponding guiding portion 142. The first storage module 20a and the controller module 30 are received in the base 10 in such a manner that the third connector 324 of the controller module 30 faces the second connector 264a of the backplane 26a. The controller module 30 and the first storage module 20a slide relative to each other until the second connector 264a on the backplane 26a is electrically coupled to the corresponding third connector 324. Therefore, the storage server is assembled.

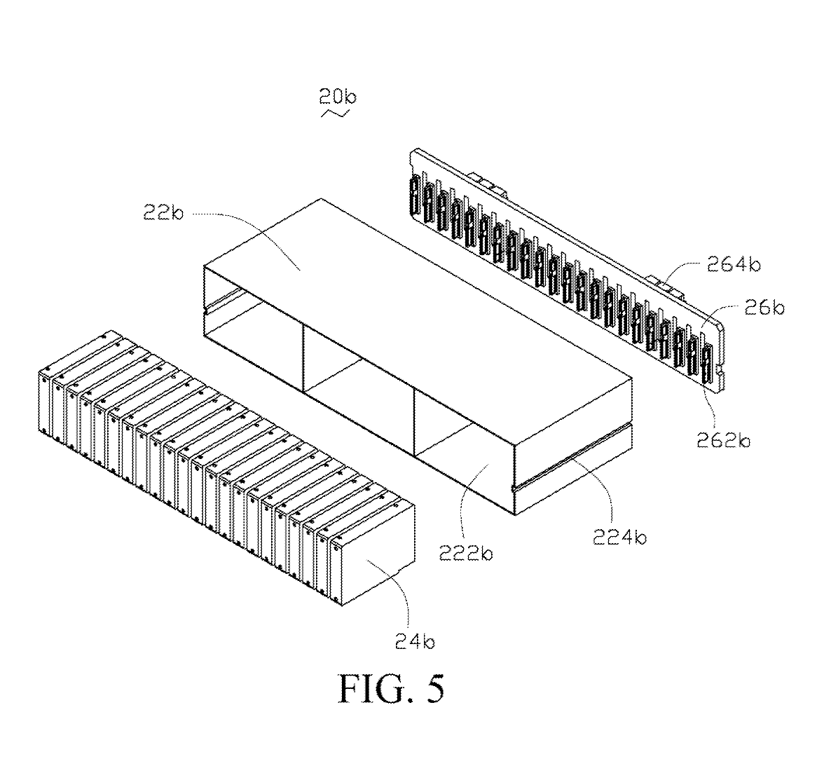

Referring to FIGS. 4 and 5, the second storage module 20b includes a bracket 22b, a plurality of second type of hard disks 24b, and a backplane 26b. The bracket 22b is generally box-shaped with two openings defined at opposite sides thereof respectively. The bracket 22b is segmented by a plurality of baffles (not labeled) into a plurality of receiving spaces 222b, each receiving space 222b receiving a predetermined amount of the second type of hard disks 24b. A slot 224b is defined in an outer surface of each side of the bracket 22b, for engaging with a corresponding guiding portion 142 of the base 10. In the embodiment, the hard disks 24b are 2.5 inch hard disks.

The backplane 26b is fixed to the second bracket 22b at one of the openings. The backplane 26b has a plurality of first connectors 262b fixed to a side thereof, facing an inner space of the bracket 22b, corresponding to the second type of hard disks 24b. The first connectors 262b are used for being connected to the connectors (not shown) provided on the second type of hard disks 24b. Further, at least a second connector 264b is fixed to an opposite side of the backplane 26b. The second connector 264b is used for connecting to the third connectors 324 of the controller module 30.

The first storage module 20a and the second storage module 20b can be selectively received in the base 10 and electrically coupled to the controller module 30. Therefore, only the bracket and the backplane are replaced when the storage server is changed to accommodate a different type of hard disk. After the hard disks are assembled, the first or the second storage module can easily slide into the base 10 to be electrically coupled to the controller module 30. Therefore, the storage server is compatible with different types of hard disks.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A storage server comprising:
a base;
a storage module removably received in the base at a side thereof, the storage module comprising:
a bracket defining at least one receiving space therein;
at least one hard disk being received in said receiving space; and
a backplane fixed to the bracket facing said at least one hard disk, for being electrically connected to said at least one hard disk, at least one first connector being fixed to the backplane; and
a controller module received at an opposite side of the base and capable of receiving a plurality of auxiliary components to serve the at least one hard disk via the backplane of the bracket, the controller module having at least one second connector for electrically connecting to said first connector of the backplane.

2. The storage server as described in claim 1, wherein said at least one hard disk comprising a third connector, and at least one fourth connector is provided on the backplane for electrically connecting to the third connector.

3. The storage server as described in claim 1, wherein a guiding portion is formed on the base; and a first slot is defined in an outer surface of the bracket for engaging with a part of the guiding portion as the bracket slides into the base.

4. The storage server as described in claim 3, wherein the controller module removably mounted to the base defines a second slot for engaging with the other part of the guiding portion of the base as the controller module slides into the base.

5. The storage server as described in claim 1, wherein the bracket is segmented into a plurality of receiving spaces, each receiving space accommodating a predetermined amount of hard disks.

6. The storage server as described in claim 1, wherein the bracket is box-shaped with two openings defined in opposite sides thereof, the backplane being fixed to the bracket at one of the openings.

7. The storage server as described in claim 6, wherein said at least one hard disk is received in the bracket from the opening opposite to the backplane.

8. A storage server comprising:
a base comprising a bottom wall and two sidewalls perpendicularly extending from opposite sides of the bottom wall respectively, the base being configured for selectively allowing at least two storage modules with different types of hard disks that have different sizes received therein to slide into; and
a controller module slidably received in the base and capable of receiving a plurality of auxiliary components configured to serve said hard disks, the controller module comprising at least one connector for selectively electrically connecting to said storage modules.

9. The storage server as described in claim 8, wherein the base further comprises at least one guiding portion for guiding said storage modules and the controller module to slide into opposite sides of the base.

10. The storage server as described in claim 9, wherein at least one slot is defined in the controller module corresponding to said guiding portion of the base, for engaging said guiding portion as the controller module slides into the base.

11. The storage server as described in claim 9, wherein said guiding portion is formed on at least one of the sidewalls.

12. The storage server as described in claim 11, wherein said guiding portion protrudes from said at least one of the sidewalls, and is parallel to the bottom wall.
